(19) United States
(12) Patent Application Publication
(10) Pub. No.: US 2013/0099338 A1
(43) Pub. Date: Apr. 25, 2013

(54) MAGNETIC MEMORY ELEMENT AND MAGNETIC MEMORY

(71) Applicants: Masahiko Nakayama, Shimonoseki-shi (JP); Tatsuya Kishi, Yokohama-shi (JP); Hiroaki Yoda, Kawasaki-shi (JP); Hisanori Aikawa, Yokohama-shi (JP); Masaru Toko, Yokohama-shi (JP)

(72) Inventors: Masahiko Nakayama, Shimonoseki-shi (JP); Tatsuya Kishi, Yokohama-shi (JP); Hiroaki Yoda, Kawasaki-shi (JP); Hisanori Aikawa, Yokohama-shi (JP); Masaru Toko, Yokohama-shi (JP)

(73) Assignee: KABUSHIKI KAISHA TOSHIBA, Tokyo (JP)

(21) Appl. No.: 13/604,537

(22) Filed: Sep. 5, 2012

(30) Foreign Application Priority Data
Oct. 24, 2011 (JP) 2011-232658

(51) Int. Cl. H01L 29/82

(52) U.S. Cl. 257/421; 257/E29.323

(57) ABSTRACT

According to one embodiment, a magnetic memory element includes a memory layer having magnetic anisotropy perpendicular to a film surface and having a variable magnetization direction, a first nonmagnetic layer provided on the memory layer, and a reference layer provided on the first nonmagnetic layer, having magnetic anisotropy perpendicular to a film surface, and having an invariable magnetization direction. An area of the memory layer is larger than that of the reference layer. Magnetization in an end portion of the memory layer is smaller than that in a central portion of the memory layer.

### CROSS-REFERENCE TO RELATED APPLICATIONS

This application is based upon and claims the benefit of priority from Japanese Patent Application No. 2011-232658, filed Oct. 24, 2011, the entire contents of which are incorporated herein by reference.

### FIELD

Embodiments described herein relate generally to a magnetic memory element and magnetic memory.

### BACKGROUND

A magnetic random access memory (MRAM) uses, as a memory element, an MTJ (Magnetic Tunnel Junction) element using the magnetoresistive effect by which a resistance value changes in accordance with the direction of magnetization. The MTJ element has a three-layered structure including a reference layer, a memory layer, and an insulating layer that is sandwiched between the reference layer and memory layer and forms a tunnel barrier. The magnetization in the reference layer is fixed in one direction and does not reverse even when a write operation is performed. On the other hand, the magnetization in the memory layer reverses due to torque externally given by a write operation.

An MRAM using a spin-transfer torque writing method of writing data by directly supplying an electric current to the MTJ element is known. When a write current is supplied to the MTJ element, the resistance value of the MTJ element changes depending on the relative directions of the two magnetic layers. That is, the resistance value of the MTJ element becomes low when the magnetization directions in the memory layer and reference layer are parallel, and becomes high when the magnetization directions are antiparallel. The MTJ element can be used as a memory element by making these low- and high-resistance states of the MTJ element correspond to binary data.

Generally, a magnetic layer having magnetic anisotropic energy higher than that of the memory layer is used as the reference layer, a leakage magnetic field generated from the reference layer is large. Therefore, the leakage magnetic field from the reference layer acts on the memory layer, and the magnetization of the memory layer becomes nonuniform, or the magnetic coercive force of the memory layer shifts. This increases a write current for switching the magnetization of the memory layer, or decreases the thermal stability of the MTJ element.

### BRIEF DESCRIPTION OF THE DRAWINGS

FIG. 1 is a sectional view showing the arrangement of an MTJ element according to the first embodiment;

FIG. 2 is a plan view of the MTJ element;

FIG. 3 is a view for explaining the influence of a leakage magnetic field applied from a reference layer to a memory layer;

FIG. 4 is a view for explaining the magnetized state of an MTJ element according to a comparative example;

FIG. 5 is a view for explaining the magnetized state of the MTJ element according to the first embodiment;

FIG. 6 is a sectional view showing the arrangement of an MTJ element according to the second embodiment;

FIG. 7 is a circuit diagram showing the arrangement of an MRAM according to the third embodiment; and

FIG. 8 is a sectional view showing the arrangement of the MRAM.

### DETAILED DESCRIPTION

In general, according to one embodiment, there is provided a magnetic memory element comprising:

a memory layer having magnetic anisotropy perpendicular to a film surface and having a variable magnetization direction;

a first nonmagnetic layer provided on the memory layer; and

a reference layer provided on the first nonmagnetic layer, having magnetic anisotropy perpendicular to a film surface, and having an invariable magnetization direction,

wherein an area of the memory layer is larger than that of the reference layer, and

magnetization in an end portion of the memory layer is smaller than that in a central portion of the memory layer.

The embodiments will be described hereinafter with reference to the accompanying drawings. In the description which follows, the same or functionally equivalent elements are denoted by the same reference numerals, to thereby simplify the description.

### First Embodiment

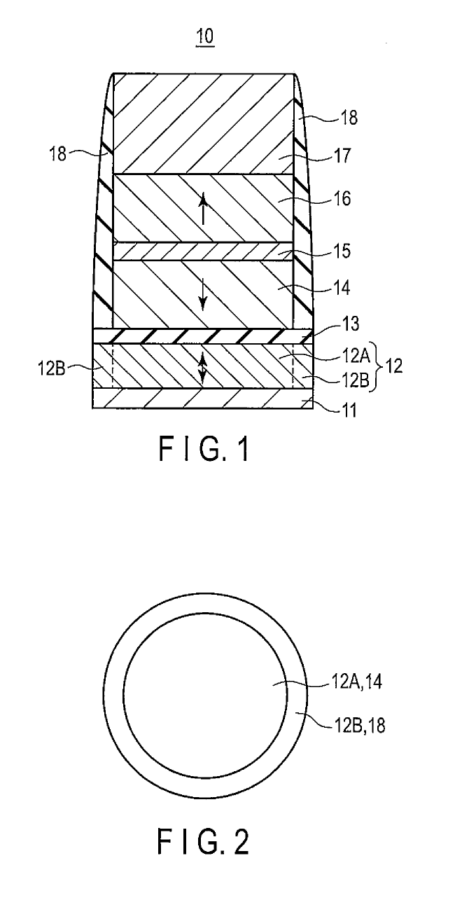

FIG. 1 is a sectional view showing the arrangement of an MTJ element 10 as a magnetic memory element according to the first embodiment. The MTJ element 10 is formed by stacking an underlayer 11, memory layer 12, nonmagnetic layer (tunnel barrier layer) 13, reference layer 14, nonmagnetic layer (spacer layer) 15, adjustment layer 16, and hard mask layer 17 in this order from below. The arrows in FIG. 1 represent magnetization. The planar shape of the MTJ element 10 is not particularly limited, and is, e.g., a circle or ellipse.

Each of the memory layer 12 and reference layer 14 is made of a ferromagnetic material, has magnetic anisotropy in a direction perpendicular to the film surfaces, and has a direction of easy magnetization perpendicular to the film surfaces. That is, the MTJ element 10 is a perpendicular magnetization type MTJ element in which the magnetization directions in the memory layer 12 and reference layer 14 are perpendicular to the film surfaces.

In the memory layer 12, the magnetization direction is variable (reverses). In the reference layer 14, the magnetization direction is invariable (fixed). The reference layer 14 is so set as to have perpendicular magnetic anisotropic energy much higher than that of the memory layer 12. The magnetic anisotropy can be set by adjusting the material configuration and/or thickness. Thus, the magnetization switching current of the memory layer 12 is decreased, thereby making the magnetization switching current of the reference layer 14 larger than that of the memory layer 12. This makes it possible to implement the MTJ element 10 including the memory layer 12 having a variable magnetization direction and the reference layer 14 having an invariable magnetization direction, with respect to a predetermined write current.

As the nonmagnetic layer 13, it is possible to use, e.g., a nonmagnetic metal, nonmagnetic semiconductor, or insulator. The nonmagnetic layer 13 is called a tunnel barrier layer when an insulator is used. As the tunnel barrier layer 13, magnesium oxide (MgO) or the like is used.

The adjustment layer 16 has a function of reducing a leakage magnetic field from the reference layer 14, thereby preventing the leakage magnetic field from being applied to the memory layer 12, and preventing the shift of the magnetic coercive force (or magnetization curve) of the memory layer 12. The memory layer 12 and reference layer 14 forming the MTJ element 10 are made of magnetic materials and hence generate magnetic fields outside. In the perpendicular magnetization type MTJ element, a leakage magnetic field generated from the reference layer 14 is generally larger than that in an in-plane magnetization type element. Also, the memory layer 12 having a magnetic coercive force smaller than that of the reference layer 14 is strongly affected by the leakage magnetic field from the reference layer 14. More specifically, the coercive magnetic force (or magnetization curve) of the memory layer 12 shifts under the influence of the leakage magnetic field from the reference layer 14, thereby increasing the magnetization switching current or decreasing the thermal stability. Therefore, the MTJ element 10 of this embodiment includes the adjustment layer 16 that reduces the leakage magnetic field to be applied from the reference layer 14 to the memory layer 12.

The adjustment layer 16 is made of a ferromagnetic material, has magnetic anisotropy perpendicular to the film surfaces, and has a direction of easy magnetization perpendicular to the film surfaces. Like the reference layer 14, the adjustment layer 16 has an invariable magnetization direction. The magnetization directions in the adjustment layer 16 and reference layer 14 are set antiparallel.

The spacer layer 15 is formed to set the magnetization directions antiparallel in the adjustment layer 16 and reference layer 14. The spacer layer 15 has a heat resistance that prevents mixing of the adjustment layer 16 and reference layer 14 in a heating step, and also has a function of controlling the crystal orientation when forming the adjustment layer 16. As the spacer layer 15, it is possible to use a nonmagnetic metal such as ruthenium (Ru), silver (Ag), or copper (Cu).

The underlayer 11 is made of a nonmagnetic material and formed to control the crystal orientation in the memory layer 12. The hard mask layer 17 is made of, e.g., a metal, and used as a mask when processing the reference layer 14, spacer layer 15, and adjustment layer 16. The hard mask layer 17 also has a function as an upper electrode. Tantalum (Ta) or the like can be used as the hard mask layer 17.

A sidewall 18 is formed to surround a multilayered film including the reference layer 14, spacer layer 15, adjustment layer 16, and hard mask layer 17. A silicon nitride or the like is used as the sidewall 18.

An example of the magnetic material of each of the memory layer 12, reference layer 14, and adjustment layer 16 is a ferromagnetic alloy containing at least one element selected from the group consisting of cobalt (Co) and iron (Fe). Another example of the magnetic material of each of the memory layer 12, reference layer 14, and adjustment layer 16 is an alloy containing at least one element selected from the group consisting of cobalt (Co) and iron (Fe), and at least one element selected from the group consisting of platinum (Pt), palladium (Pd), and chromium (Cr). Still another example of the magnetic material of each of the memory layer 12, reference layer 14, and adjustment layer 16 is a multilayered film formed by alternately stacking an alloy containing at least one element selected from the group consisting of cobalt (Co) and iron (Fe), and an alloy containing at least one element selected from the group consisting of platinum (Pt), palladium (Pd), and chromium (Cr).

The area of the memory layer 12 is larger than that of the reference layer 14. When the MTJ element 10 is projected from above, a portion of the memory layer 12 which overlaps the reference layer 14 is called a central portion 12A, and a portion of the memory layer 12 which extends from the reference layer 14 is called an end portion (peripheral portion) 12B. FIG. 2 is a plan view for explaining the planar shapes of the memory layer 12 and reference layer 14. Note that the planar shapes of the tunnel barrier layer 13 and underlayer 11 are almost the same as that of the memory layer 12. In this embodiment, the reference layer 14, spacer layer 15, and adjustment layer 16 are first processed by using the hard mask layer 17 as a mask and the tunnel barrier layer 13 as an etching stopper. Subsequently, the sidewall 18 is formed around the reference layer 14, spacer layer 15, adjustment layer 16, and hard mask layer 17, and the underlayer 11, memory layer 12, and tunnel barrier layer 13 are processed by using the sidewall 18 as a mask.

This embodiment uses a spin-transfer torque writing method by which a write current is directly supplied to the MTJ element 10 and the magnetized state of the MTJ element 10 is controlled by using the write current. The MTJ element 10 can take one of a low-resistance state and high-resistance state in accordance with whether the relative magnetization directions in the memory layer 12 and reference layer 14 are parallel or antiparallel.

When a write current flowing from the memory layer 12 to the reference layer 14 is supplied to the MTJ element 10, the relative magnetization directions in the memory layer 12 and reference layer 14 become parallel. In this parallel state, the MTJ element 10 has the lowest resistance value and is set in the low-resistance state. The low-resistance state of the MTJ element 10 is defined as, e.g., data “0”.

On the other hand, when a write current flowing from the reference layer 14 to the memory layer 12 is supplied to the MTJ element 10, the relative magnetization directions in the memory layer 12 and reference layer 14 become antiparallel. In this antiparallel state, the MTJ element 10 has the highest resistance value and is set in the high-resistance state. The high-resistance state of the MTJ element 10 is defined as, e.g., data “1”.

Thus, the MTJ element 10 can be used as a memory element capable of storing one-bit data (binary data). It is possible to freely set the allocation between the resistance states of the MTJ element 10 and data.

When reading data from the MTJ element 10, a read voltage is applied to the MTJ element 10, and the resistance value of the MTJ element 10 is detected based on the read current flowing through the MTJ element 10 in this state. The read voltage is set at a value much smaller than the threshold value of magnetization reversal caused by spin-transfer torque.

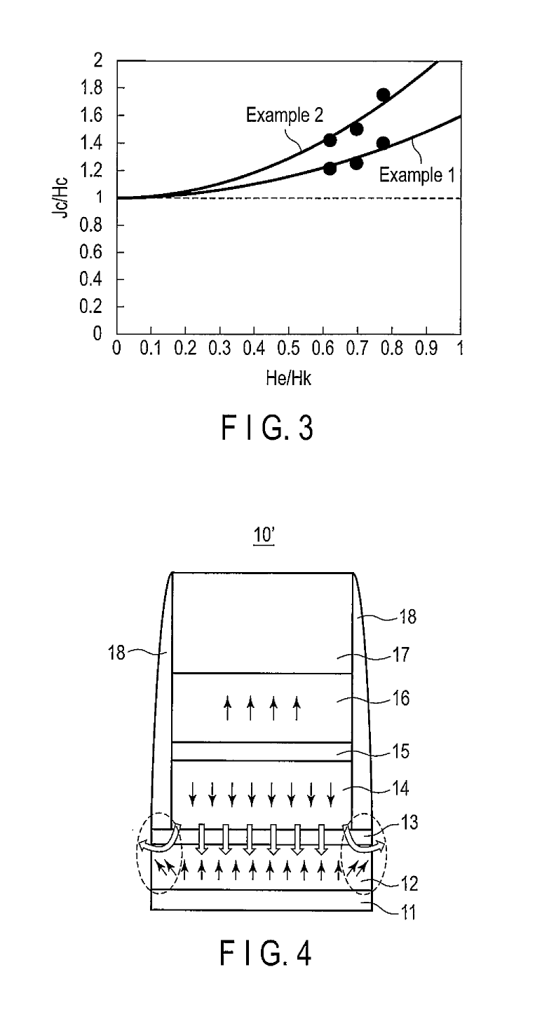

FIG. 3 is a view for explaining the influence of the leakage magnetic field applied from the reference layer to the memory layer. FIG. 3 shows the graphs of two examples (Examples 1 and 2). Referring to FIG. 3, the ordinate indicates Jc/Hc, and the abscissa indicates He/Hk. Jc is the switching current density, and Hc is the magnetic coercive force of the memory layer. That is, the numerical values on the ordinate of FIG. 3 are normalized by the magnetic coercive force Hc. He is the in-plane direction component of the leakage magnetic field applied from the reference layer to the end portion of the memory layer, and Hk is the anisotropic magnetic field of the memory layer.

To implement a magnetic memory element capable of writing data with a small write current and holding information for a long time, it is necessary to decrease the switching current density Jc and increase the magnetic coercive force Hc of the memory layer. Accordingly, a high Jc/Hc is undesirable. As can be understood from FIG. 3, Jc/Hc increases when the in-plane direction component of the leakage magnetic field applied from the reference layer to the end portion of the memory layer increases. As is understandable from FIG. 3, therefore, it is necessary to reduce the in-plane direction component He of the leakage magnetic field from the reference layer.

FIG. 4 is a view for explaining the magnetized state of an MTJ element 10′ according to a comparative example. Referring to FIG. 4, thin arrows represent magnetization, and thick arrows represent the leakage magnetic field from the reference layer 14. The whole memory layer 12 of the MTJ element 10′ is made of a ferromagnetic material. A leakage magnetic field in the central portion of the reference layer 14 is perpendicular to the film surfaces and uniform. By contrast, a leakage magnetic field in the end portion of the reference layer 14 is oblique to the film surfaces and nonuniform. That is, the leakage magnetic field in the end portion of the reference layer 14 contains the in-plane direction component in addition to the perpendicular direction component.

The leakage magnetic field in the end portion of the reference layer 14 inclines magnetization in the end portion of the memory layer 12 outward (in the in-plane direction). This is so because the area of the memory layer 12 is larger than that of the reference layer 14. This makes the magnetization in the memory layer 12 nonuniform. The nonuniform magnetization in the memory layer 12 interferes with coherent magnetization reversal in the memory layer 12. As a consequence, a write current for causing magnetization reversal in the memory layer 12 increases, the thermal stability of the memory layer 12 degrades.

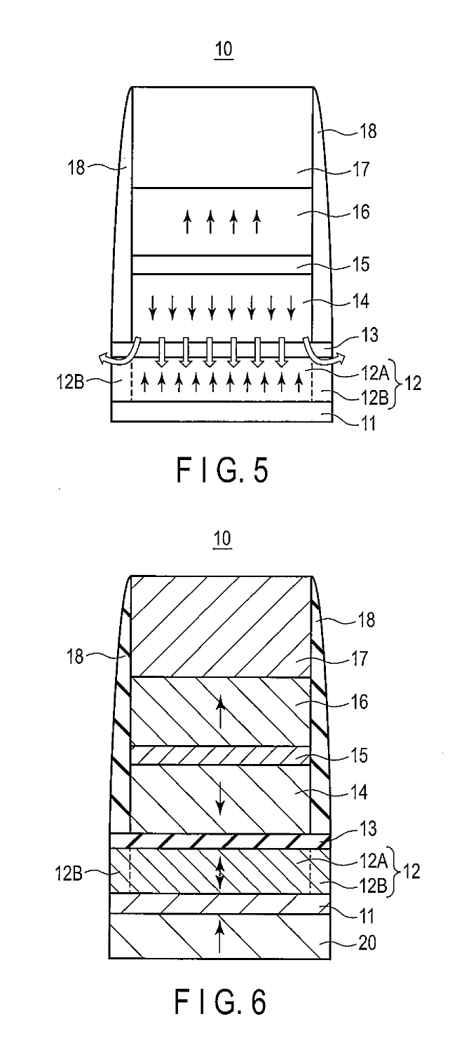

In this embodiment, therefore, the magnetization in the end portion 12B of the memory layer 12 is made smaller than that in the central portion 12A. Desirably, the end portion 12B of the memory layer 12 is given no magnetization, i.e., the end portion 12B of the memory layer 12 is demagnetized. FIG. 5 is a view for explaining the magnetized state of the MTJ element 10 according to this embodiment. Since the end portion 12B of the memory layer 12 has no magnetization, the magnetization in the central portion 12A is the main component of the magnetization in the memory layer 12. Although the leakage magnetic field from the end portion of the reference layer 14 is applied to the end portion 12B of the memory layer 12 as in the comparative example, the leakage magnetic field has no influence on the magnetization of the whole memory layer 12 because the end portion 12B of the memory layer 12 has no magnetization. Since this makes it possible to prevent the magnetization in the memory layer 12 (more specifically, the magnetization in the central portion 12A) from becoming nonuniform, coherent magnetization reversal in the memory layer 12 can be implemented. Consequently, the write current for causing magnetization reversal in the memory layer 12 can be reduced.

Note that the inner circumference of the end portion 12B to be demagnetized need not be in the same position as that of the outer circumference of the reference layer 14, and may also be positioned inside the outer circumference of the reference layer 14. That is, an area of the central portion 12A of the memory layer 12 may be less than or equal to that of the reference layer 14. When the inner circumference of the end portion 12B to be demagnetized is positioned inside the outer circumference of the reference layer 14, it is possible to further prevent the nonuniform leakage magnetic field in the end portion of the reference layer 14 from being applied to the central portion 12A of the memory layer 12.

Examples of the method of reducing or eliminating the magnetization in the end portion 12B of the memory layer 12 are (1) adding (implanting) an impurity such as arsenic (As), germanium (Ge), or antimony (Sb) to the end portion 12B of the memory layer 12, and (2) oxidizing or nitriding the end portion 12B of the memory layer 12. That is, the end portion 12B of the memory layer 12 is formed by adding an impurity to the same material as that of the central portion 12A.

### EFFECTS

In the first embodiment as described in detail above, in the MTJ element 10 in which the memory layer 12, tunnel barrier layer 13, reference layer 14, spacer layer 15, and adjustment layer 16 are stacked in this order, the area of the memory layer 12 is set larger than that of the reference layer 14. Also, the magnetization in the end portion 12B of the memory layer 12 is set smaller than that in the central portion 12A of the memory layer 12.

In the first embodiment, therefore, even when the leakage magnetic field (containing the in-plane direction component) from the end portion of the reference layer 14 is applied to the end portion 12B of the memory layer 12, it is possible to prevent the magnetization in the memory layer 12 from becoming nonuniform. This makes it possible to implement coherent magnetization reversal in the memory layer 12, and reduce the write current for causing magnetization reversal in the memory layer 12. In addition, the data retention characteristic can be improved because the thermal stability of the MTJ element 10 can be improved.

Also, the magnetization in the central portion 12A is the main component of the magnetization in the memory layer 12, it is unnecessary to accurately process the memory layer 12. Since this facilitates processing the underlayer 11, memory layer 12, and tunnel barrier layer 13 by using the sidewall 18 as a mask, the manufacturing cost of the MTJ element 10 can be reduced.

Furthermore, the MTJ element 10 includes the adjustment layer 16 for preventing the leakage magnetic field of the reference layer 14 from acting on the memory layer 12. This makes it possible to prevent the magnetization in the memory layer 12 from becoming nonuniform, and prevent the shift of the magnetic coercive force of the memory layer 12.

Note that the adjustment layer 16 is not always necessary, and the MTJ element 10 can also be formed without the adjustment layer 16. That is, the hard mask layer 17 is formed on the reference layer 14 in FIG. 1. Coherent magnetization reversal in the memory layer 12 can be implemented even in the MTJ element 10 having this arrangement.

### Second Embodiment

In the second embodiment, two adjustment layers are prepared to reduce a leakage magnetic field from a reference layer, and an MTJ element 10 is formed by sandwiching the reference layer and a memory layer between the two adjustment layers. FIG. 6 is a sectional view showing the arrangement of the MTJ element 10 according to the second embodiment.

In addition to the multilayered structure shown in FIG. 1, an adjustment layer 20 for reducing a leakage magnetic field from a reference layer 14 is formed under an underlayer 11. The adjustment layer 20 is made of the same ferromagnetic material as that of an adjustment layer 16, has magnetic anisotropy perpendicular to the film surfaces, and has a direction of easy magnetization perpendicular to the film surfaces. Like the reference layer 14, the adjustment layer 20 has an invariable magnetization direction. The magnetization direction in the adjustment layer 20 is set antiparallel to that in the reference layer 14. That is, the reference layer 14 and adjustment layer 20 antiferromagnetically couple with each other with the underlayer (nonmagnetic layer) 11 being interposed between them.

The area of the adjustment layer 20 is almost the same as that of the memory layer 12. That is, the adjustment layer 20 is processed simultaneously with the memory layer 12 by using a sidewall 18 as a mask. A central portion 12A of the memory layer 12 is positioned inside the outer circumference of the adjustment layer 20. Therefore, a leakage magnetic field from the adjustment layer 20 is uniformly applied to the central portion 12A of the memory layer 12. That is, a nonuniform leakage magnetic field generated from the end portion of the adjustment layer 20 is not applied to the central portion 12A of the memory layer 12. Accordingly, the magnetization in the central portion 12A of the memory layer 12 does not become nonuniform due to the leakage magnetic field from the adjustment layer 20.

In the MTJ element 10 formed as described above, it is possible to further reduce the influence the leakage magnetic field from the reference layer 14 on the memory layer 12. This makes it possible to prevent the magnetization in the memory layer 12 from becoming nonuniform, and prevent the shift of the magnetic coercive force of the memory layer 12. Other effects are the same as those of the first embodiment.

Note that the MTJ element 10 may also include only the adjustment layer 20 below the memory layer 12. That is, the MTJ element 10 may also be formed by omitting the adjustment layer 16 in FIG. 6. It is possible to prevent the shift of the magnetic coercive force of the memory layer 12 even in the MTJ element 10 having this arrangement.

### Third Embodiment

The third embodiment is a configuration example when an MRAM (magnetic memory) is formed by using an MTJ element 10 described above. As the MTJ element 10, either of the MTJ elements explained in the first and second embodiments can be used.

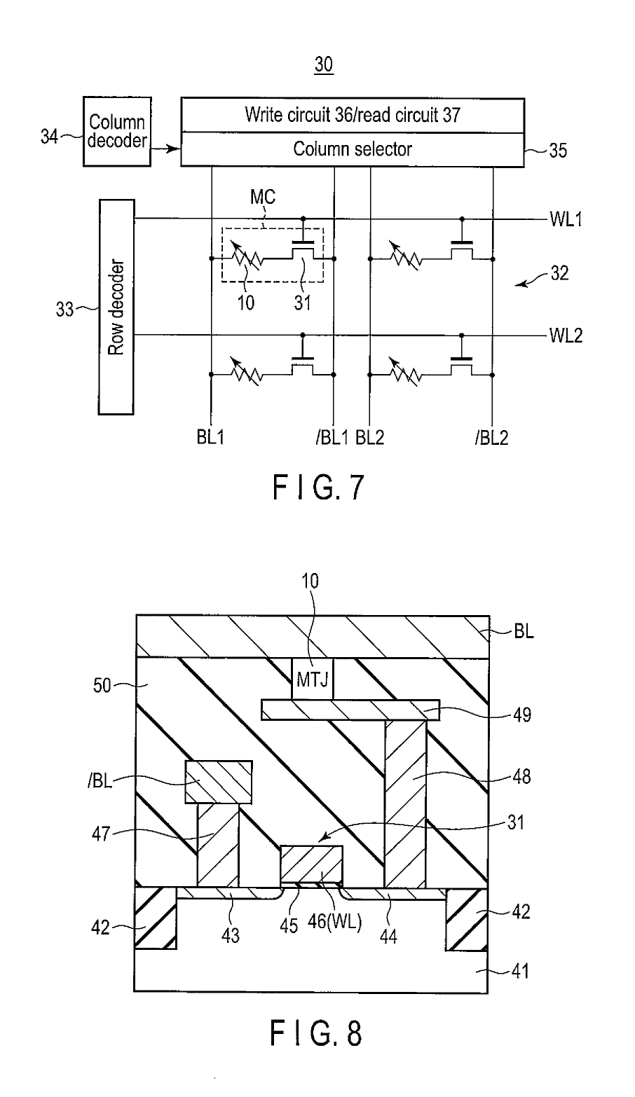

FIG. 7 is a circuit diagram showing the arrangement of an MRAM 30 according to the third embodiment. The MRAM 30 includes a memory cell array 32 including a plurality of memory cells MC arranged in a matrix. Note that FIG. 7 shows (2×2) memory cells MC as an example. The memory cell array 32 includes a plurality of pairs of bit lines BL and /BL running in the column direction. The memory cell array 32 also includes a plurality of word lines WL running in the row direction.

The memory cells MC are arranged at the intersections of the bit lines and word lines. Each memory cell MC includes the MTJ element 10 and a selection transistor 31. The selection transistor 31 is, e.g., an N-channel MOSFET (Metal Oxide Semiconductor Field Effect Transistor). One terminal of the MTJ element 10 is connected to the bit line BL. The other terminal of the MTJ element 10 is connected to the drain of the selection transistor 31. The gate of the selection transistor 31 is connected to the word line WL. The source of the selection transistor 31 is connected to the bit line /BL.

A row decoder 33 is connected to the word lines WL. The row decoder 33 selects one of the plurality of word lines WL based on a row address.

A write circuit 36 and read circuit 37 are connected to the pairs of bit lines BL and /BL via a column selector 35. The column selector 35 includes, e.g., N-channel MOSFETs equal in number to all the bit lines, and selects a pair of bit lines BL and /BL necessary for an operation in accordance with an instruction from a column decoder 34. The column decoder 34 decodes a column address, and supplies the decoded signal to the column selector 35.

The write circuit 36 receives externally supplied write data. The write circuit 36 applies a write voltage to a pair of bit lines BL and /BL connected to a selected memory cell as a write target. The write circuit 36 then writes the data in the selected memory cell by supplying a write current to the selected memory cell.

The read circuit 37 applies a read voltage to a selected memory cell as a read target. Then, the read circuit 37 detects data stored in the selected memory cell based on a read current flowing through the selected memory cell. The data read by the read circuit 37 is output outside.

Data write to the memory cell MC is performed as follows. First, to select the memory cell MC as a data write target, the row decoder 33 activates the word line WL connected to the selected memory cell MC. This turns on the selection transistor 31. In addition, the column decoder 34 selects the pair of bit lines BL and /BL connected to the selected memory cell MC.

In this state, one of bidirectional write currents is supplied to the MTJ element 10 in accordance with write data. More specifically, when supplying the write current to the MTJ element 10 from the left to the right in FIG. 7, the write circuit 36 applies a positive voltage to the bit line BL and the ground voltage to the bit line /BL. When supplying the write current to the MTJ element 10 from the right to the left in FIG. 7, the write circuit 36 applies a positive voltage to the bit line /BL and the ground voltage to the bit line BL. Consequently, data “0” or “1” can be written to the memory cell MC.

Data read from the memory cell MC is performed as follows. First, the selection transistor 31 of the selected memory cell MC is turned on in the same manner as in data write. The read circuit 37 supplies a read current flowing, e.g., from the right to the left in FIG. 7 to the MTJ element 10. This read current is set at a value much smaller than the threshold value of magnetization reversal caused by spin-transfer torque. Then, the read circuit 37 detects the resistance value of the MTJ element 10 based on the read current. Consequently, data stored in the MTJ element 10 can be read.

Next, a structure example of the MRAM 30 will be explained. FIG. 8 is a sectional view showing the arrangement of the MRAM 30. An element isolation insulating layer 42 having an STI (Shallow Trench Isolation) structure is formed in a P-type semiconductor substrate 41. An N-channel MOSFET as the selection transistor 31 is formed in an element region (active area) surrounded by the element isolation insulating layer 42. The selection transistor 31 includes a source region 43 and drain region 44 formed apart from each other in the element region, a gate insulating film 45 formed on a channel region between the source region 43 and drain region 44, and a gate electrode 46 formed on the gate insulating film 45. The gate electrode 46 corresponds to the word line WL shown in FIG. 7. Each of the source region 43 and drain region 44 is an N-type diffusion region.

A contact plug 47 is formed on the source region 43. The bit line /BL is formed on the contact plug 47. A contact plug 48 is formed on the drain region 44. An extraction electrode 49 is formed on the contact plug 48. The MTJ element 10 is formed on the extraction electrode 49. The bit line BL is formed on the MTJ element 10. An interlayer dielectric layer 50 fills the portion between the semiconductor substrate 41 and bit line BL.

In the third embodiment as described in detail above, the MRAM 30 can be formed by using either of the MTJ elements 10 explained in the first and second embodiments.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A magnetic memory element comprising:
a memory layer having magnetic anisotropy perpendicular to a film surface and having a variable magnetization direction;
a first nonmagnetic layer provided on the memory layer; and
a reference layer provided on the first nonmagnetic layer, having magnetic anisotropy perpendicular to a film surface, and having an invariable magnetization direction,
wherein an area of the memory layer is larger than that of the reference layer, and
magnetization in an end portion of the memory layer is smaller than that in a central portion of the memory layer.

2. The element of claim 1, wherein the end portion of the memory layer is made of a material formed by adding an impurity to a material of the central portion of the memory layer.

3. The element of claim 2, wherein the impurity is selected from the group consisting of arsenic (As), germanium (Ge), and antimony (Sb).

4. The element of claim 1, wherein the end portion of the memory layer is oxidized or nitrided.

5. The element of claim 1, wherein the end portion of the memory layer has no magnetization.

6. The element of claim 1, wherein an area of the central portion of the memory layer is less than or equal to that of the reference layer.

7. The element of claim 1, wherein the magnetization in the central portion of the memory layer is uniform.

8. The element of claim 1, further comprising:
a second nonmagnetic layer provided on the reference layer; and
an adjustment layer provided on the second nonmagnetic layer and having magnetization antiparallel to that of the reference layer.

9. The element of claim 1, further comprising:
a second nonmagnetic layer provided under the memory layer; and
an adjustment layer provided under the second nonmagnetic layer and having magnetization antiparallel to that of the reference layer.

10. The element of claim 1, further comprising:
a second nonmagnetic layer provided on the reference layer;
a first adjustment layer provided on the second nonmagnetic layer and having magnetization antiparallel to that of the reference layer;
a third nonmagnetic layer provided under the memory layer; and
a second adjustment layer provided under the third nonmagnetic layer and having magnetization antiparallel to that of the reference layer.

11. The element of claim 1, further comprising a sidewall provided on the first nonmagnetic layer and around the reference layer.

12. The element of claim 11, wherein an outer circumference of the sidewall is the same as that of the memory layer.

13. A magnetic memory comprising a magnetic memory element of claim 1.

14. The memory of claim 13, further comprising:
a first bit line electrically connected to one terminal of the magnetic memory element;
a selection transistor electrically connected to the other terminal of the magnetic memory element;
a second big line electrically connected to one terminal of the selection transistor; and
a word line electrically connected to a gate of the selection transistor.
